(19) United States
(12) Patent Application Publication
(10) Pub. No.: US 2018/0065327 A1
(43) Pub. Date: Mar. 8, 2018

(54) ELECTROMAGNETIC INTERFERENCE SUPPRESSION DEVICE AND METHOD FOR MANUFACTURING SAME

(71) Applicant: LITTELFUSE, INC., Chicago, IL (US)

(72) Inventors: Jianhua Chen, Sunnyvale, CA (US); Chun-Kwan Tsang, Morgan Hill, CA (US)

(73) Assignee: LITTELFUSE, INC., Chicago, IL (US)

(21) Appl. No.: 15/131,203

(22) Filed: Apr. 18, 2016

(51) Int. Cl. B29C 70/88; B29C 70/82; H05K 9/00

(52) U.S. Cl. CPC B29C 70/885; H05K 9/0084; B29C 70/82

(57) ABSTRACT

A method for manufacturing an EMI suppression device includes formulating a dielectric material from a polymer composite material that includes a thermoplastic resin /thermosetting resin and a conductive filler. A sheet that comprises the polymer composite filler is prepared. The top surface of the sheet is then laminated with a conductive foil. The laminated sheet is cut into one or more sections, where each section has a laminated top surface and a middle section that comprises the polymer composite material.

### BACKGROUND

### Field

The present invention relates generally to electrical noise reduction means.

More specifically, the present invention relates to an electromagnetic interference (EMI) suppression device and method for manufacturing the same.

### Description of Related Art

Motors, especially DC motors that utilize brushes to drive a commutator, are known to generate electrical noise (i.e., electromagnetic interference or EMI) capable of interfering with the operation of nearby electronic equipment. To alleviate EMI problems, motors may be fitted with various types of filters specifically configured to reduce the EMI to acceptable levels.

The EMI filter may include components such as capacitors and inductors that are connected together via soldering. The assembled EMI filter may then be inserted into a metal housing of the motor.

However, assembling the various components may be complex, especially for small motor housings that provide very confined spaces for placement of the components. This complexity increases assembly time and the likelihood of manufacturing defects. This, in turn, necessarily increases manufacturing costs of the motor assembly.

Other problems with existing motor assemblies will become apparent in view of the disclosure below.

### SUMMARY

In one aspect, a method for manufacturing an EMI suppression device includes formulating a dielectric material from a polymer composite material that includes a thermoplastic resin/ thermosetting resin and a conductive filler. A sheet that comprises the polymer composite filler is prepared. The top surface of the sheet is then laminated with a conductive foil. The laminated sheet is cut into one or more sections, where each section has a laminated top surface and a middle section that comprises the polymer composite material. A capacitance of the section, measured between the laminated top surface and a bottom surface of the section, varies based on a ratio of the conductive filler to the thermoplastic resin in the polymer composite material.

In a second aspect, an EMI suppression device includes a dielectric formed of polymer composite material that includes a thermoplastic or thermosetting resin and a conductive filler. A capacitance of the dielectric between a top surface and a bottom surface of the dielectric is set according to a ratio of the conductive filler to the thermoplastic resin in the polymer composite material.

### BRIEF DESCRIPTION OF THE DRAWINGS

FIG. 1 illustrates exemplary operations for manufacturing an exemplary EMI suppression device;

FIGS. 2A-2C illustrate various stages of the EMI suppression device during the manufacturing process of FIG. 1;

FIGS. 3A and 3B illustrate the exemplary EMI suppression device coupled to a protection device;

FIG. 4A is a chart that illustrates the performance characteristics of the EMI suppression device in an exemplary application; and

FIG. 4B is a chart that illustrates the performance characteristics of other filters in the application of FIG. 4A.

### DETAILED DESCRIPTION

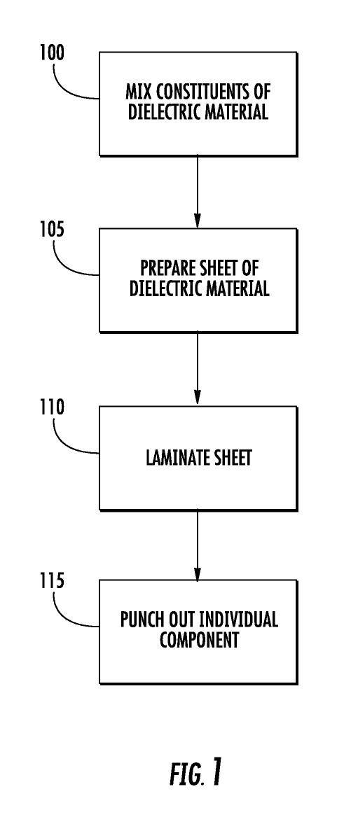

FIG. 1 illustrates exemplary operations for manufacturing an EMI suppression device. At block 100, a dielectric material may be formulated from a polymer composite material that includes a thermoplastic or thermosetting resin a conductive filler. For example, a thermoplastic resin such as polyethane-co-tetrafluoroethane, a thermosetting resin such as epoxy, or a different thermoplastic or thermosetting resin may be utilized.

The conductive filler may correspond to a mixture of one or more of copper, tin, carbon, nickel, a different metal material and a metal ceramic material. The tin and carbon may be provided in a powder or fiber form. The copper may be provided in the form of dendrite particles, fiber particles, or powder particles. In the case of dendrite particles, the particles may have a length of about 25 μm and a diameter of about 5 μm. Tin particles may have a length of about 30 μm. The size and shape of the different conductive particles may be adjusted as the case may be to change the electrical characteristics of the conductive filler.

In some implementations, the conductive filler may make up between about 5% and 50% of the volume of the polymer composite material.

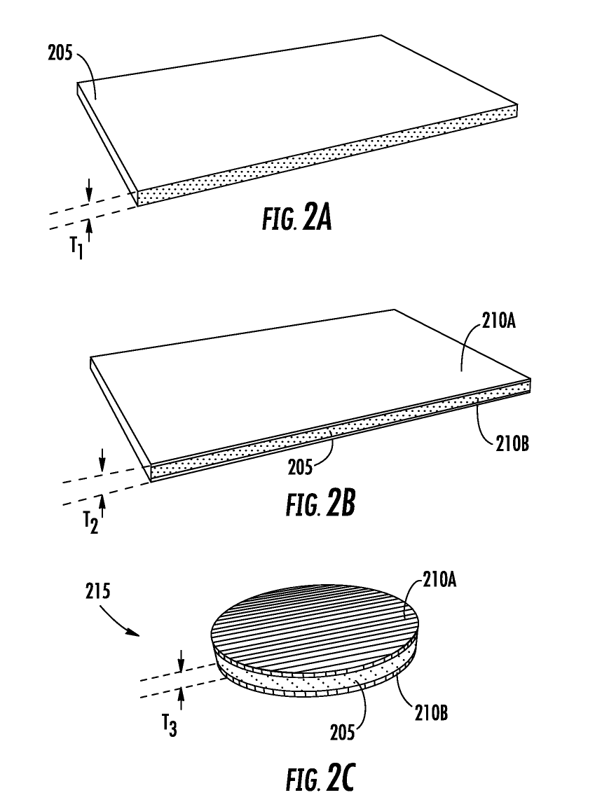

At step 105, a sheet of polymer composite material 205 may be prepared, as illustrated in FIG. 2A. For example, polymer composite material may be rolled, compressed or otherwise flattened into a sheet of polymer composite material 205. The distance or thickness, Ti, between the top and bottom surfaces of the sheet of polymer composite material 205 may be between about 5 mil and 500 mil. The distance may be selected along with a final surface area of the EMI suppression device to provide a specified capacitance. For example, a capacitance of 15 of at 1 Mhz frequency may be achieved when the Cu—Sn alloy loading is 20% by volume, the area of the top and bottom surfaces is about 1.27 cm²and the thickness of the sheet is 40 mil.

At step 110, the top and/or bottom surfaces of the sheet of polymer composite material 205 may be laminated as illustrated in FIG. 2B. For example, a nodular metal foil 210AB (i.e., a foil having an irregular surface) may be laminated onto the top and bottom surfaces of the sheet of polymer composite material 205 with the nodular side of the metal foil facing the sheet of polymer composite material 205. The nodular metal foil 210AB may be bonded to the sheet of polymer composite material 205 by pressing the nodular metal foil 210AB and sheet of polymer composite material 205 together. In some implementations, the sheet of polymer composite material 205 and/or the nodular metal foil 210AB may be pre-heated to a temperature of about polymer melting point and a pressure of 1000 psi may be applied to compress the portions together. Spacer may be needed to control the thickness of the materials. The pressure may be applied for about 5 minutes to allow time for a sufficiently strong bond to occur between the sheet of polymer composite material 205 and the nodular metal foil 210AB. The distance or thickness, T2, between the top and bottom surfaces of the combined nodular metal foil 210AB and sheet of polymer composite material 205 may be between about 5 mil and 500 mil.

At block 115, the sheet may be singulated. That is, the sheet may be cut into sections, where each section corresponds to an EMI suppression device, such as the exemplary EMI suppression device 215 illustrated in FIG. 2C. In this regard, the electrodes of the EMI suppression device 215 may correspond to the nodular metal foil 210AB on the top and bottom surfaces of the EMI suppression device 215. The dielectric of the EMI suppression device 215 may correspond to the polymer composite material 205. In one exemplary implementation, for a top surface area of 1.27 cm², a dielectric thickness, T3, off 40 mil, and a polymer composite material comprising 15% vol. of CuSn, the capacitance of the EMI suppression device 215 may be about 1.56×10² nF.

The capacitance of the EMI suppression device 215 may be selected by adjusting the ratio of conductive filler material to thermoplastic or thermosetting resin in the polymer composite material 205. Table 1 below illustrates the capacitance of the EMI suppression device 215 for a 1 mm thick polymer composite material 205 of ETFE and CuSN.

TABLE 1

| % Volume of CuSn | Capacitance (nF at 1 MHz) |
|---|---|
| 0 | 8.29 × 10⁻⁴ |
| 10 | 2.77 × 10⁻³ |
| 15 | 1.56 × 10² |
| 20 | 1.50 × 10⁴ |
| 30 | 4.70 × 10⁴ |
| 40 | 5.60 × 10⁴ |

As shown, the capacitance of the EMI suppression device 215 may be changed by simply adjusting the amount of conductive filler. For example, when no conductive filler is used, the capacitance at 1 MHz may be about 8.29×10⁻⁴ nf. When the conductive filler is about 40% of the polymer composite material 205, the capacitance may be about 5.60×10⁴ nf.

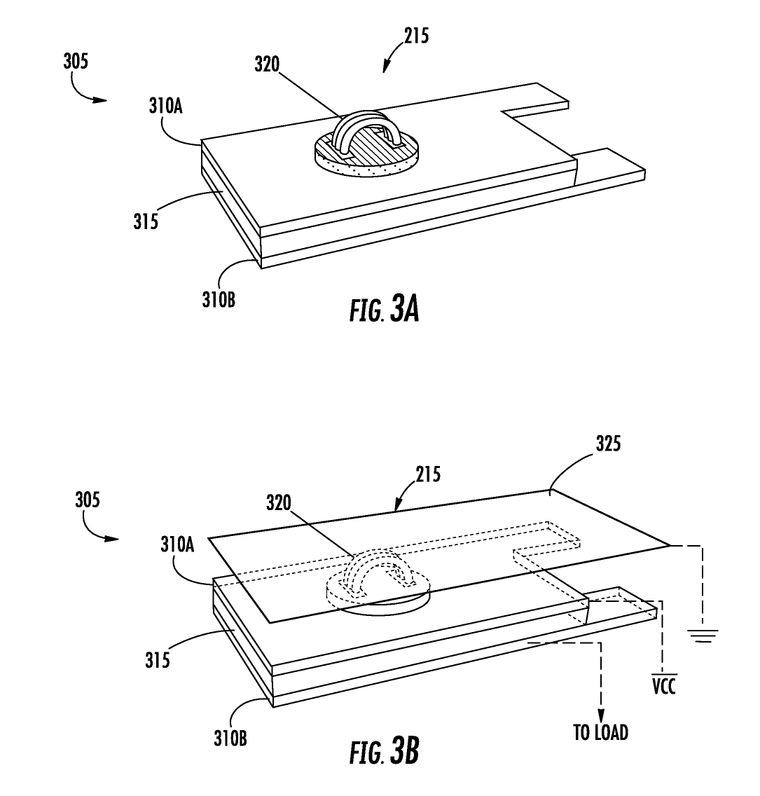

FIGS. 3A and 3B illustrate one use case for the exemplary EMI suppression device 215 for suppressing EMI noise generated by a load. In FIG. 3A, one side of the exemplary EMI suppression device 215 is coupled to a terminal 310A of a positive temperature coefficient (PTC) device 305. One or more conductive resilient members 320 may be coupled to the other side of the EMI suppression device 215.

The PTC device 305 includes a PTC material 315 along with top and bottom conductive surfaces or terminals 310AB. The PTC device 305 operates by allowing current flow between the top and bottom conductive surfaces when the temperature of the PTC material 315 is below an activation threshold of the PTC material 315. For example, the resistance may be below 0.05 ohm when the temperature of the PTC material 315 is below 160° C. When the temperature of the PTC material 315 exceeds the activation temperature, the resistance may abruptly increase to a resistance of about 1×10⁴ ohm or more to thereby substantially limit current flow through the PTC device 305.

As illustrated in FIG. 3B, a first terminal 310A of the PTC device 305 may be coupled to a power source (Vcc) for powering the load. The second terminal 310B may be coupled to the load itself. In this way, current may flow from the power source, through the PTC device 305, and then to the load.

The resilient members 320 coupled to the EMI suppression device 215 may be coupled to a conductive surface that is in turn coupled to a ground of the power supply.

One exemplary use case for such an assembly is in a motor. For example, the load may correspond to a motor and the conductive surface 325 may correspond to a housing of the motor that is grounded. In operation, noise present on the power line to the load (VCC) generated by the motor is shunted to ground via the EMI suppression device 215.

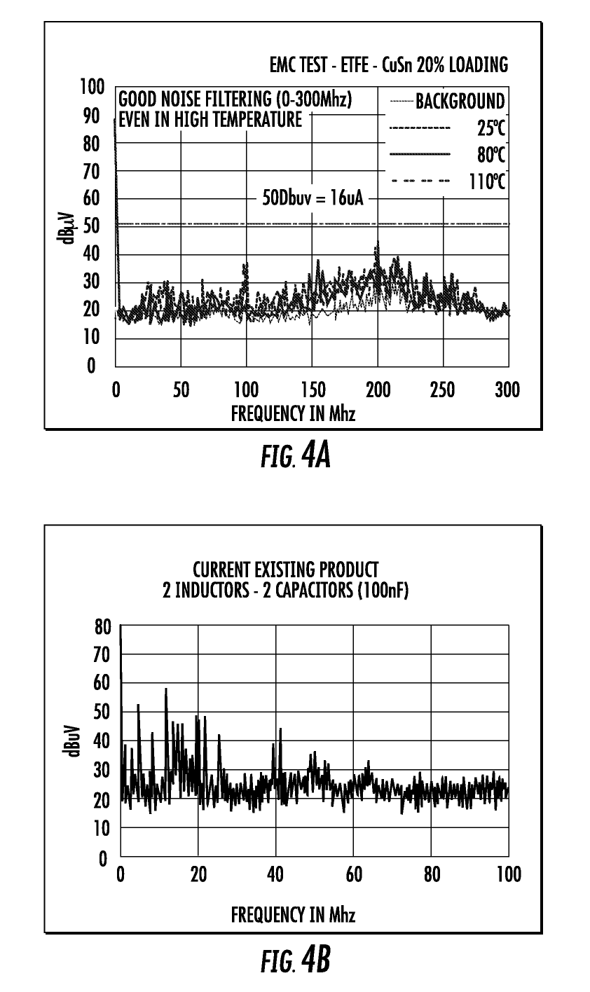

FIG. 4A is a chart that illustrates the performance characteristics of the EMI suppression device 215 in such an application. As shown, the magnitude of the EMI noise is reduced to just under 20 DBμV for frequencies under 100 MHz.

By contrast, a typical filter for filtering EMI noise generated by a motor usually consists of a pair of inductors in series with respective terminals of the motor and a pair of ceramic capacitors connected respectively to other ends of the inductors for shorting EMI noise generated by the motor to a common ground node. FIG. 4B illustrates the effectiveness of such a configuration. As shown, the EMI noise is about 25 DBμV for frequencies under 100 MHz, which is worse than the performance characteristics shown in FIG. 4A.

Other advantages realized by replacing the two capacitors with a single EMI suppression device include increased cost effectiveness as compared to existing filtering solutions. For example, the cost of the EMI suppression device 215 may less than other solutions. The performance of EMI suppression device 215 is consistent in harsh environments such as at temperatures up to 110° C. The capacitance value of the of EMI suppression device 215 may be easily tailored by adjusting the proportion of conductive material in the polymer composite material. The polymer composite material of the EMI suppression device 215 is less fragile than a ceramic disk and, therefore, is easy to handle and assemble. There are no significant limitations on the size and thickness of the EMI suppression device 215.

While the method for manufacturing the electromagnetic interference suppression device has been described with reference to certain embodiments, it will be understood by those skilled in the art that various changes may be made and equivalents may be substituted without departing from the spirit and scope of the claims of the application. Other modifications may be made to adapt a particular situation or material to the teachings disclosed above without departing from the scope of the claims. Therefore, the claims should not be construed as being limited to any one of the particular embodiments disclosed, but to any embodiments that fall within the scope of the claims.

We claim:

1. A method for manufacturing an electromagnetic interference (EMI) suppression device, the method comprising:
formulating a dielectric material from a polymer composite material that includes a thermoplastic resin and a conductive filler;
preparing a sheet that comprises the polymer composite material;
laminating a top surface of the sheet with a conductive foil; and
singulating the sheet into one or more sections, each section having a laminated top surface and a middle section that comprises the polymer composite material.

2. The method according to claim 1, further comprising laminating a bottom surface of the sheet with the conductive foil to thereby provide a singulated section having a laminated bottom surface.

3. The method according to claim 1, wherein the thermoplastic resin corresponds to poly ethane-co-tetrafluoroethane.

4. The method according to claim 1, wherein the conductive filler corresponds a mixture of one or more of: copper, tin, and carbon.

5. The method according to claim 4, wherein the conductive filler corresponds to a mixture of copper particles having a dendrite shape with a length of about 25 μm and a diameter of about 5 μm, and tin particles having a length of about 30 μm.

6. The method according to claim 1, wherein between 5% and 60% of a volume of the polymer composite material is conductive filler.

7. The method according to claim 1, wherein the conductive foil corresponds to a nodular metal foil.

8. An EMI suppression device comprising:
a dielectric formed of polymer composite material that includes:
a thermoplastic resin; and
a conductive filler.

9. The EMI suppression device according to claim 8, further comprising a laminated conductive foil disposed on a top and a bottom surface of the dielectric.

10. The EMI suppression device according to claim 8, wherein the thermoplastic resin corresponds to polyethane-co-tetrafluoroethane, thermosetting epoxy.

11. The EMI suppression device according to claim 8, wherein the conductive filler corresponds a mixture of one or more of: copper, tin, carbon, a metal material and a metal ceramic material.

12. The EMI suppression device according to claim 11, wherein the conductive filler corresponds to a mixture of copper particles having a dendrite shape with a length of about 25 μm and a diameter of about 5 μm, and tin particles having a length of about 30 μm.

13. The EMI suppression device according to claim 8, wherein between 5% and 60% of a volume of the polymer composite material is conductive filler.

14. The EMI suppression device according to claim 8, wherein the conductive filler is a nodular metal foil.
